(19) United States
(12) Patent Application Publication
(10) Pub. No.: US 2007/0075365 A1
(43) Pub. Date: Apr. 5, 2007

(54) Thin-film transistor and method of making the same

(76) Inventors: Peter Mardilovich, Corvallis, OR (US); Randy Hoffman, Corvallis, OR (US); Gregory Herman, Albany, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/242,511

(22) Filed: Oct. 3, 2005

(51) Int. Cl. H01L 27/12

(52) U.S. Cl. 257/347

(57) ABSTRACT

A thin-film transistor includes a substrate having a substantially outwardly protruding support structure formed thereon such that a portion adjacent to the structure is exposed. The support structure has opposed sidewalls sloped at an angle relative to the substrate surface. A stack is established over the portion and over a portion of an adjacent opposed sidewall. The stack includes an insulating layer. A channel material is established on at least a portion of the stack, thus forming a channel having a length substantially determined by a thickness of the insulating layer in relation to the adjacent opposed sidewall angle. A gate dielectric is established on at least a portion of the channel material and a gate electrode is established on at least a portion of the gate dielectric.

### BACKGROUND

The present disclosure relates to thin-film transistors and method(s) of making the same.

Many factors may influence the operating frequency of thin-film transistors. Some non-limitative examples of these factors include the carrier mobility of the channel material used and the length of the channel (i.e. the separation between the source and drain electrodes). As the maximum operating frequency of a thin-film transistor is roughly proportional to the inverse square of the transistor's channel length, a reduced channel length may substantially increase the operation frequency of the transistor.

Further, the channel length may also influence the ability of the thin-film transistor to carry current as the drain current is roughly proportional to the inverse of the channel length (assuming constant channel width).

One process for reducing channel length (i.e. achieving reduced separation between source and drain electrodes) in a thin-film transistor involves direct photolithographic patterning. This process, however, may be limited in the channel dimensions that are capable of being formed, and may require relatively strict control of processes and processing conditions. Additional direct patterning approaches capable of achieving smaller channel dimensions include electron-beam lithography, imprint lithography, and the like. In general, however, such direct-patterning approaches may become increasingly complex as the minimum feature size to be patterned decreases.

Other approaches for reducing channel length include forming a vertical thin-film transistor structure, in which the source and drain electrodes are aligned in a vertical fashion (i.e., one electrode is located substantially over, or above, the other electrode), and channel current flows between the source and drain electrodes in a vertical (i.e., normal to the plane of the substrate) direction. In a vertical thin-film transistor structure, the separation between source and drain electrodes is typically defined by the thickness of an interposed film layer, and thus may be relatively precise and uniform (as determined by the thickness precision and uniformity of the interposed layer). Vertical structures generally include a high-quality channel layer deposited on a vertical sidewall, which may increase process complexity and topography of the resulting structure.

As such, it would be desirable to provide a method of forming a thin-film transistor having a reduced channel length, in which the channel length dimension is defined without direct patterning of features at this dimension.

### SUMMARY

The present disclosure provides a thin-film transistor. The thin-film transistor includes a substrate having a substantially outwardly protruding support structure formed thereon such that a portion adjacent to the structure is exposed. The support structure has opposed sidewalls sloped at an angle relative to the substrate surface. A stack is established over the portion and over a portion of an adjacent opposed sidewall. The stack includes an insulating layer. A channel material is established on at least a portion of the stack, thus forming a channel having a length substantially determined by a thickness of the insulating layer in relation to the adjacent opposed sidewall angle. A gate dielectric is established on at least a portion of the channel material and a gate electrode is established on at least a portion of the gate dielectric.

### BRIEF DESCRIPTION OF THE DRAWINGS

Features and advantages of the present disclosure will become apparent by reference to the following detailed description and drawings, in which like reference numerals correspond to similar, though not necessarily identical components. For the sake of brevity, reference numerals or features having a previously described function may not necessarily be described in connection with other drawings in which they appear.

FIGS. 1A through 1J are semi-schematic cross-sectional views of an embodiment of a method of forming two thin-film transistors;

FIG. 2 is a semi-schematic top view of an embodiment similar to the method step depicted in FIG. 1D, showing patterned elements/layers;

FIG. 3 is a semi-schematic top view of the embodiment of the thin-film transistors depicted in FIG. 1J;

FIG. 4 is a semi-schematic view of an embodiment of a thin-film transistor formed on one side of a support structure;

FIG. 5 is a semi-schematic view of an embodiment of two thin-film transistors formed on an alternate embodiment of a support structure;

FIG. 6 is a semi-schematic view of an embodiment of two thin-film transistors formed on still another alternate embodiment of a support structure;

FIG. 7 is a semi-schematic view of an alternate embodiment of two thin-film transistors; and

FIG. 8 is a semi-schematic view of still another alternate embodiment of two thin-film transistors.

### DETAILED DESCRIPTION

Embodiment(s) of the disclosed method(s) form thin-film transistors advantageously having a top-gate structure and substantially planar channel geometry with respect to a substrate. The thin-film transistors may be suitable for use in a variety of electronic devices, including, but not limited to display devices. The methods disclosed herein advantageously allow for controlling the channel length to the sub-micron scale, generally without the direct patterning of films on this dimensional scale. Without being bound to any theory, it is believed that the methods disclosed herein may form a thin-film transistor with dimensions beyond the limitations of direct photolithographic patterning. For example, dimensions ranging from about 10 nm to about 1 μm may be achieved using embodiment(s) of the method disclosed herein and without using direct photolithographic patterning to obtain such dimensions.

It is to be understood that the terms “disposed on/over”, “deposited on/over,” “established on/over” and the like are broadly defined herein to encompass a variety of divergent layering arrangements and assembly techniques. These arrangements and techniques include, but are not limited to (1) the direct attachment of one material layer to another material layer with no intervening material layers therebetween; and (2) the attachment of one material layer to another material layer with one or more material layers therebetween provided that the one layer being “disposed on/over,” “deposited on/over,” or “established on/over” the other layer is somehow “supported” by the other layer (notwithstanding the presence of one or more additional material layers therebetween). The phrases “directly established on” and the like are defined herein to encompass a situation(s) wherein a given material layer is secured to another material layer without any intervening material layers therebetween.

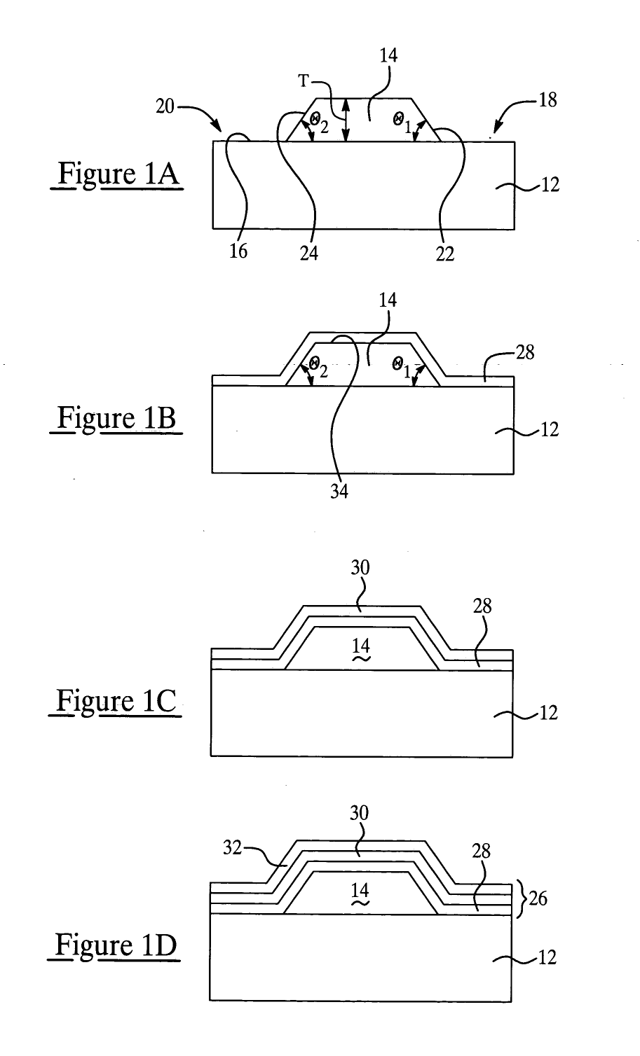

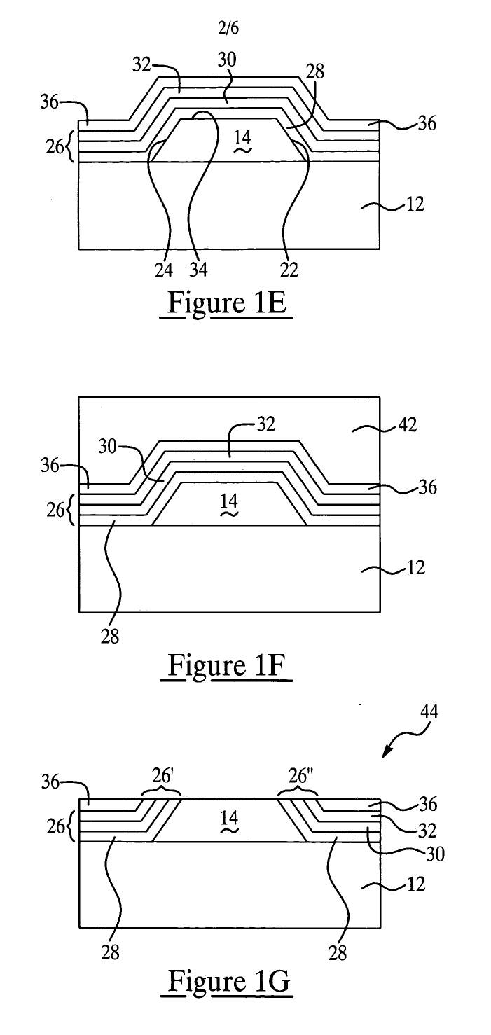

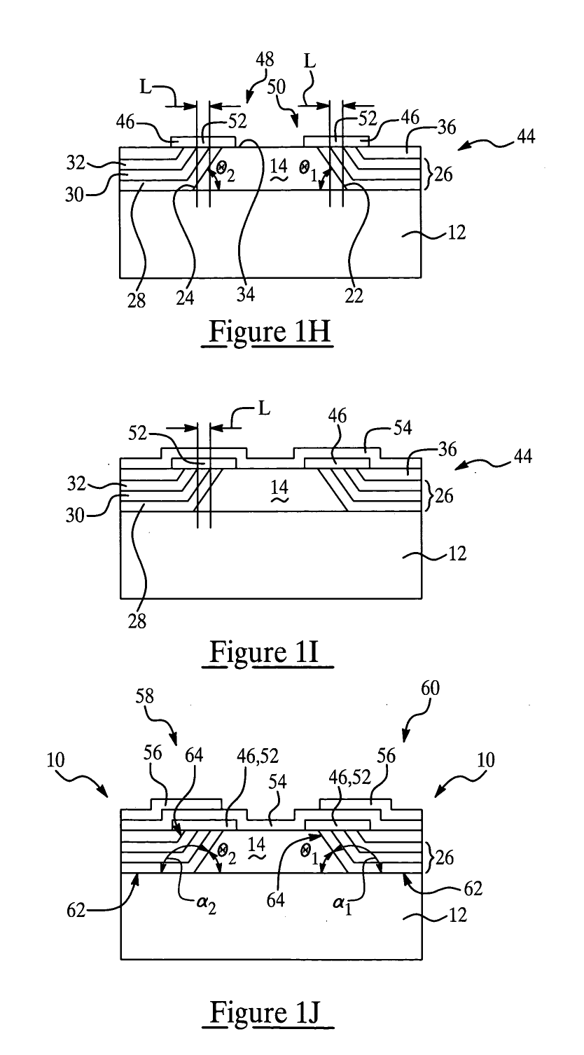

Referring now to FIGS. 1A through 1J together, an embodiment of the method of forming two thin-film transistors 10 (see FIG. 1J) is shown.

FIG. 1A depicts a substrate 12 having a substantially outwardly protruding support structure 14 formed on at least a portion of its surface 16, or on a portion of layer(s) (not shown) previously established on the substrate surface 16. It is to be understood that any suitable substrate 12 may be selected. A non-limitative example of a suitable material includes substantially rigid organic materials. Specific examples of suitable substrate 12 materials include, but are not limited to silicon, quartz, sapphire, glass, plexiglass, polyamides, metals (a non-limitative example of which include stainless steel), polyethylene naphthalate (PEN), polyethylene terephthalate (PET), and/or mixtures thereof. In an embodiment, substrate 12 is a rigid material having a layer established thereon prior to fabricating the support structure 14 thereon. A non-limitative example of such a layer includes a polymer film.

Generally, the support structure 14 is formed so that at least a portion 18, 20 adjacent to the structure 14 (e.g. these may be portions of the substrate surface 16, and/or portions of layers established on the substrate surface 16) remains exposed. It is to be understood that the support structure 14 may have any suitable shape, as long as the shape includes opposed sidewalls 22, 24 that are sloped at an angle θ₁, θ₂ relative to the substrate surface 16. In a non-limitative example, the angles θ₁, θ₂ are about 90°, and in another non-limitative example, the angles are other than about 90° (see FIG. 1J, FIG. 5 and FIG. 6 for examples of support structures 14 having sidewall angles other than about 90°). In still another non-limitative example, the angles θ₁, θ₂ are greater than about 5° relative to the substrate surface 16. It is to be further understood that, in an embodiment, the sidewalls 22, 24 may have an arcuate shape, and thus may be characterized by many different angles β₁, β₂ . . . βₙ (see FIG. 6). In such a case, the angles θ¹, θ₂ are also determined relative to the substrate surface 16, but may vary depending upon at which tangent line (two examples of which are shown in connection with angles β₁, β₂) on the arcuate sidewalls 22, 24 the angles θ₁, θ₂ are determined.

Non-limitative examples of suitable support structure 14 shapes include regular geometric shapes, such as, for example, a generally convex shape, a substantially trapezoidal shape, a substantially arcuate shape, a substantially bell-curve shape, and/or the like, or irregular geometric shapes. It is to be understood that the sidewalls 22, 24 may have substantially equal heights (as shown in FIG. 1A) or substantially irregular heights. As shown in FIG. 1A, the support structure 14 has a thickness T that ranges from about 200 nm to about 5000 nm. In an alternate embodiment, the thickness T ranges from about 200 nm to about 500 nm. The width of the support structure 14 ranges from about 250 nm to about 100 μm. It is to be understood that these dimensions are examples, and the support structure 14 may have other dimensions, which may be limited by the size of the substrate 12.

In an embodiment (not shown in the Figures), the support structure 14 is formed by establishing a support material layer on the substrate surface 16. It is to be understood that the support material layer may form, through further processing, the support structure 14 that may be used in forming a thin-film transistor 10.

In an embodiment, the support material layer is etchable, and in another embodiment, the support material layer is malleable. Non-limitative examples of suitable support material layer materials include oxides (e.g. a plasma enhanced chemical vapor deposition (PECVD) oxide), such as tetraethylorthosilicate (TEOS) or a low-stress TEOS, nitrides, and/or the like. It is to be understood that when the support material layer having an appropriate etch rate is selected, the support material layer may be etched to form the support structure 14, as discussed below.

A photoresist layer may be established on the support material layer. This layer may be patterned to aid in forming the support structure 14 having that pattern. The thickness of the photoresist layer may be chosen based on, at least in part, the etch rate of the photoresist layer, the etch rate of the support material layer, and/or the desired dimensions of support structure 14. In an embodiment, the photoresist layer ranges from about 0.5 to about five microns in thickness.

The photoresist layer may be patterned via selective exposure (e.g. using a lithographic mask) to radiation, such as in a photolithography process. The pattern may also be formed, for instance, using imprint or e-beam lithography. Generally the pattern resembles the shape of the sidewalls 22, 24. Heating the patterned photoresist may alter its cross-sectional shape. Thus, through baking the photoresist at higher temperatures, or at lower temperatures for a longer time period (also called “hard baking”), a sharp angle (e.g., about 90°) of what ultimately becomes the sidewalls 22, 24 may be altered to an acute angle. Through baking, the pattern becomes more dome-like, thereby altering the sidewalls' angle. It is to be understood that the pattern may be baked until the pattern's cross-sectional shape has sidewalls of a desired angle.

Unpatterned portions of the photoresist and the support material layer are removed. Removal of the unpatterned parts may be accomplished, for example, by etching, vaporization, gravity (e.g., pouring off fluidified parts of the layers), and the like.

The photoresist layer and the support material layer may then be etched to create the support structure 14. The etchant etches away the patterned photoresist layer and the support material layer, but in so doing the pattern protects part of the support material layer from the etchant, thereby leaving the support structure 14 of the support material layer. An example of a technique for forming a support structure 14 may be found in U.S. Pat. application Ser. No. 10/817,729 filed on Apr. 2, 2004.

In another non-limitative example, the support structure may be formed by depositing a layer of silicon oxide, or other like material, on the substrate 12 and then etching the silicon oxide to form the support structure 14. In still another non-limitative example, the support structure 14 may be a metal formed via wet etching processes.

Referring now to FIGS. 1B through 1D, a stack 26 (shown in FIG. 1D) of materials is established on at least one of the exposed portions 18, 20 and on the support structure 14. In the embodiment depicted in these figures, each layer 28, 30, 32 of the stack 26 is established substantially adjacent both of the exposed portions 18, 20, and adjacent the sidewalls 22, 24 and a top 34 of the substantially outwardly protruding support structure 14.

FIG. 1B depicts a source or a drain electrode 28 established directly on at least a portion of the substrate 12 and on the support structure 14. It is to be understood, however, that the source or drain electrode 28 may be established on any layer(s) that may be present on the substrate 12. The source or drain electrode 28 may be deposited and patterned using any suitable techniques.

FIG. 1C depicts an insulating layer 30 established on the source or drain electrode 28. The insulating layer 30 may be any suitable insulating material, a non-limitative example of which includes an inorganic dielectric layer, such as, for example, silicon oxide, silicon nitride, aluminum oxide, and/or the like. Such materials may be established using physical vapor deposition (PVD), chemical vapor deposition (CVD), atomic layer deposition (ALD), and/or the like, in combination with photolithography, imprinting, and/or the like.

In an embodiment, the insulating layer 30 may be formed from the source or drain electrode 28. In this non-limitative example, the source or drain electrode 28 may be made of an electrochemical oxidizable (e.g. anodizable) material, such as, for example, aluminum, tantalum, tungsten, niobium, titanium, alloys thereof, and/or combinations thereof. Electrochemical oxidation of a portion of the source or drain 28 forms the insulating layer 30.

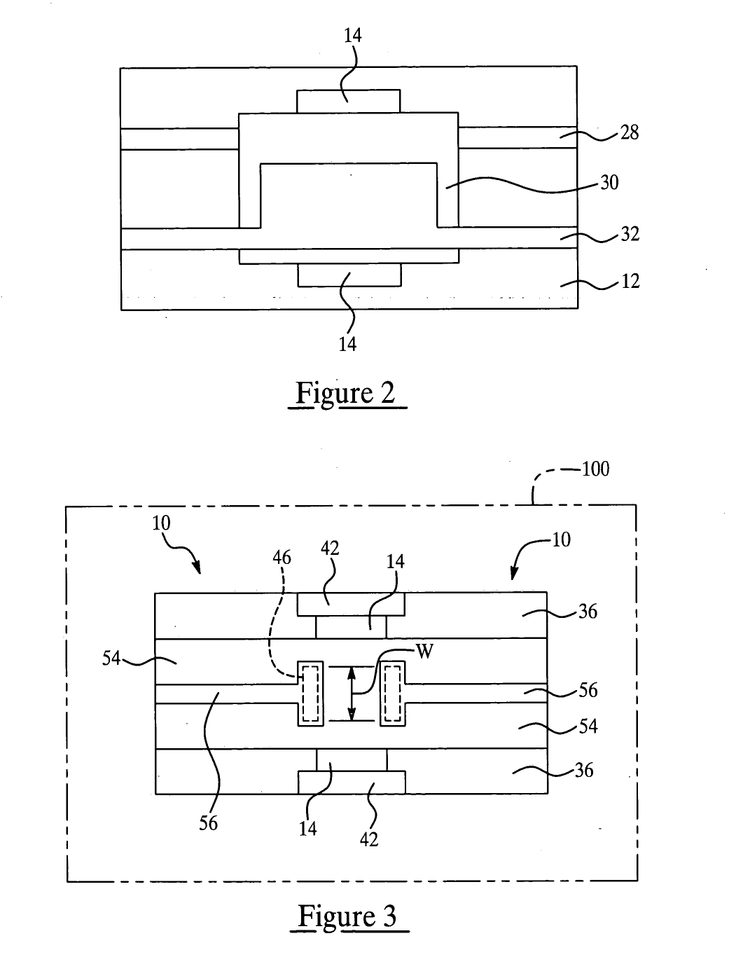

FIG. 1D depicts the other of a drain or source electrode 32 established on the insulating layer 30 so that it at least partially overlaps with the source or drain electrode 28 in the regions adjacent the sidewalls 22, 24 of the support structure 14. It is to be understood that if a source electrode is established as electrode 28, then a drain electrode is established as electrode 32, and vice versa. The other of the drain or source electrode 32 may be established using any suitable deposition techniques and patterning techniques. FIG. 2 shows a top view of an embodiment similar to the method step shown in FIG. 1D, however FIG. 2 further illustrates a non-limitative example of how the source 28, drain 32, and insulating layer 30 may be patterned. It is to be understood that the elements/layers 28, 30, 32 of the stack 26 may be patterned in any desirable configuration so the source and drain electrodes 28, 32 at least partially overlap in the regions adjacent the sidewalls 22, 24. It is to be further understood that patterning is generally performed prior to planarization processes. In an alternate embodiment, however, patterning may be performed after planarization processes.

Referring now to FIG. 1E, an optional stopper layer 36, that is suitable for use with chemical-mechanical planarization (CMP), may be established on the stack 26. The stopper layer 36 may be an insulating material having a thickness (prior to planarization) ranging from about 100 nm to about 1 μm. The stopper layer 36 generally has a relatively low rate of polishing and may be relatively easily detected (e.g. via optical techniques). It is to be understood that the stopper layer 36 may function as a partial planarization stop during subsequent planarization processes. Non-limitative examples of the stopper layer 36 include metals (such as titanium or tantalum), silicon nitride, and/or combinations thereof.

FIG. 1F depicts a fill layer 42 established on the stopper layer 36. In an embodiment where the stopper layer 36 is not used, the fill layer 42 is established on the other of the drain/source electrode 32, and on any remaining exposed areas, for example, exposed areas of the substrate 12. The fill layer 42 may advantageously assist in facilitating subsequent planarization processes. The fill layer 42 may be any suitable material, including, but not limited to silicon oxide, amorphous silicon, spin-on-glass, and/or the like, and/or combinations thereof. It is to be understood that generally the fill layer 42 has a thickness that results in a film that equals or exceeds the height of the stack 26, as shown in FIG. 1F. The fill layer 42 may also be deposited to have any suitable thickness, a non-limitative example of which ranges from about 200 nm to about 10 μm.

Referring now to FIG. 1G, at least a portion of the fill layer 42, a portion of the stack 26, and a portion of the support structure 14 are removed via planarization, such that a substantially planar structure 44 is formed. Planarization may be accomplished via a chemical-mechanical planarization (CMP) process. In an embodiment incorporating the stopper layer 36, it is to be understood that planarization may be performed until a desirable portion of stopper layer 36 is revealed, as such, the stopper layer 36 may act as a partial planarization stop. In this embodiment, the planarization process re-exposes the stopper layer(s) 36, a remaining portion of the support structure 14, and the film stack 26 at two discrete top surface regions 26′, 26″. It is to be understood that after planarization, a portion of the fill layer 42 may remain (see, for example, FIG. 3).

In an embodiment without the optional stopper layer 36, planarization may be performed until the support structure 14 and regions (for example 26′, 26″) of the stack 26 are exposed to form the substantially planar structure 44. In this embodiment, the fill layer 42 may be part of the substantially planar structure 44.

FIG. 1H depicts thin-film transistor channel material 46 established on the two discrete top surface regions 26′, 26″ of the stack 26. The channel material 46 may also be established on at least a portion of (a non-limitative example of which includes two opposed ends 48, 50) the top 34 of the support structure 14 and on a portion of each of the stopper layers 36, if present. The channel material 46 may be established via a deposition process and a patterning process. Non-limitative examples of suitable channel materials 46 include hydrogenated amorphous silicon (a-Si:H); poly-crystalline silicon (poly-Si); oxide semiconductors including, but not limited to zinc oxide, tin oxide, indium oxide, gallium oxide, and/or combinations thereof (non-limitative examples of which include zinc tin oxide and zinc indium oxide); and organic semiconductors including, but not limited to poly(3-hexylthiophene) (P3HT), pentacene; and/or the like; and/or combinations thereof.

A channel 52 is provided by at least a portion of the channel material 46. In an embodiment, the channel 52 is defined by the channel material 46 adjacent an area between the source and drain electrodes 28, 32. It is to be understood that the channel 52 is substantially planar and substantially parallel to the substrate surface 16. The width W of the channel 52 (see FIG. 3) is substantially defined by the width of the channel material 46 and/or the width of the source and drain electrodes 28, 32, depending, at least in part, on the specific layout selected for the final thin-film transistor 10. The length L of the channel 52 is substantially determined by a thickness of the insulating layer 30 in relation to the angle θ₁, θ₂ of the sidewall 22, 24 positioned nearest the channel 52. Generally the channel length L may be determined using the following equation:
L=t/sin(θ)
where t is the thickness of the insulating layer 30 and θ is the angle (with respect to the substrate surface 16) of the sidewall 22, 24 positioned nearest the particular channel 52. In the non-limitative example shown in FIG. 1F, θ₁ is about 45°, and the channel length L is equal to t/sin(45°). Embodiments of the channel length L are measurable on a sub-micron scale. Further, it is to be understood that the sub-micron dimensions may be advantageously achieved substantially without direct patterning on a scale of this dimension.

Referring now to FIG. 11, a gate dielectric 54 is established on the channel material(s) 46. In an embodiment, the gate dielectric 54 is also established on the exposed areas of the substantially planar structure 44, including exposed areas of the support structure 14 and at least a portion of the exposed areas of each of the stopper layers 36, if present. The gate dielectric 54 may be established via any suitable deposition process and patterning process. Non-limitative examples of materials suitable for the gate dielectric 54 include inorganic dielectrics (non-limitative examples of which include silicon oxide, silicon nitride, silicon oxynitride, aluminum oxide, hafnium oxide, zirconium oxide, tantalum oxide, and combinations thereof); organic dielectrics (non-limitative examples of which include UV curable acrylic monomers, acrylic polymers, UV curable monomers, thermal curable monomers, polymer solutions including, but not limited to melted polymer and/or oligomer solutions, poly methyl methacrylate, poly vinylphenol, benzocyclobutene, one or more polyimides, and combinations thereof); and/or inorganic/organic composites including combinations of the above-listed materials.

FIG. 1J depicts the thin-film transistors 10 formed by an embodiment of the method disclosed herein. In an embodiment of the method, a gate electrode 56 is established on at least a portion (and in this embodiment on two portions 58, 60) of the gate dielectric 54. The gate electrode 56 may be established via any suitable deposition process and patterning process. Non-limitative examples of materials suitable for the gate electrode 56 include metals (non-limitative examples of which include aluminum, silver, titanium, molybdenum, gold, palladium, platinum, copper, nickel, and/or combinations thereof), conductive oxides (non-limitative examples of which include n-type doped indium oxide, tin oxide, zinc oxide, and/or the like, and/or combinations thereof), and/or combinations thereof.

Each thin-film transistor 10 (and 10′, 10″ described further hereinbelow) is a top-gate structure.

Each thin-film transistor 10 shown in FIG. 1J has a stack 26, one of which is established over one portion 18 and over at least a portion of the adjacent opposed sidewall 22, and the other of which is established over the other portion 20 and over at least a portion of the adjacent opposed sidewall 24. In other words, each stack 26 has two unitary members 62, 64 offset from each other at an angle α₁, α₂ supplementary to the angle θ₁, θ₂ of the adjacent opposed sidewall 22, 24. The members 62, 64 include the source/drain electrode 28, the insulating layer 30, and the other of the drain/source electrode 32.

In an embodiment, each of the thin-film transistors 10 has a total thickness of about 1 μm. In a non-limitative example, the total thickness of the thin-film transistor 10 results from the source/drain electrode 28 having a thickness of about 200 nm, the insulating layer 30 having a thickness of about 200 nm, the other of the drain/source electrode 32 having a thickness of about 200 nm, the optional stop layer 36 or remaining fill layer 42 having a thickness of about 200 nm, the channel 52 having a thickness of about 50 nm, the gate dielectric 54 having a thickness of about 100 nm, and the gate electrode 56 having a thickness of about 200 nm.

Referring now to FIG. 3, a top view of the thin-film transistors 10 shown in FIG. 1J is depicted. The elements depicted in this view include the gate electrodes 56, a portion of the gate dielectric 54, a portion of the stopper layers 36, portions of the support structure 14, and fill layer 42 that may remain after planarization. The channel materials 46 are hidden in this embodiment, as they are established beneath the gate electrodes 56 and the gate dielectric 54. In this embodiment, the width W of the channels 52 extends substantially along the width of the channel materials 46.

FIG. 3 also schematically depicts the thin-film transistors 10 operatively disposed in a display device 100.

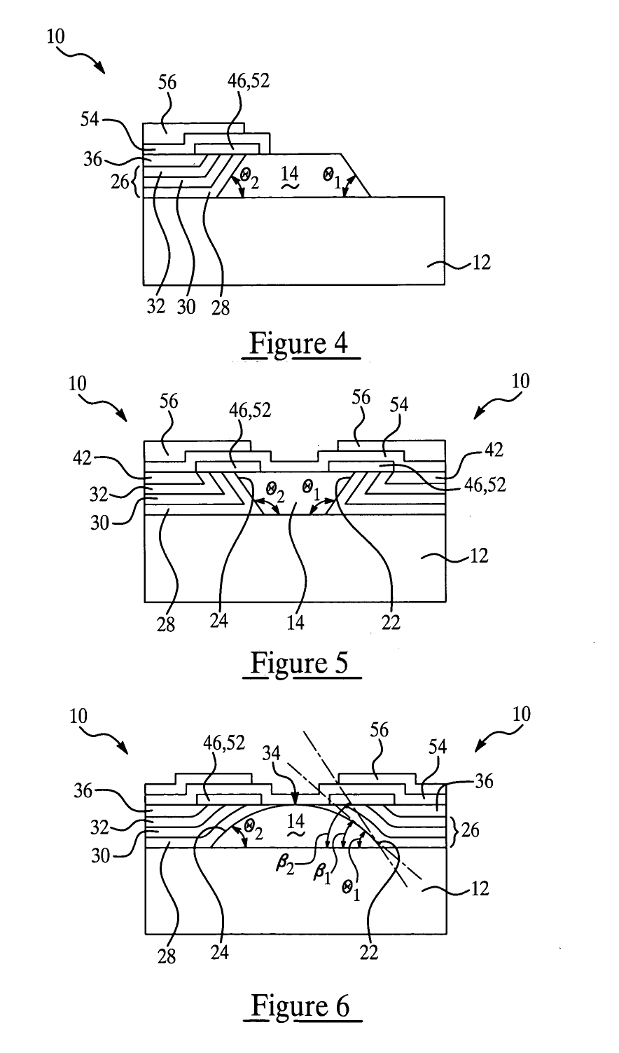

While the embodiment of the method shown in FIGS. 1A-lJ illustrates forming two thin-film transistors 10 using both of the opposed sidewalls 22, 24 of the support structure 14 and both exposed portions 18, 20 for the formation of two stacks 26, it is to be understood that a thin-film transistor 10 may be formed using one of the opposed sidewalls 22, 24 and one of the exposed portions 18, 20. The thin-film transistor 10 formed on one of the opposed sidewalls 22, 24 and on one of the exposed portions 18, 20 is shown in FIG. 4.

Referring now to FIG. 5, two thin-film transistors 10 are formed on an alternate embodiment of the support structure 14. As depicted, this support structure 14 has sidewall angles θ¹, θ₂ that are greater than about 90°. Generally, in forming this embodiment of the thin-film transistors 10, conformal deposition techniques (e.g. chemical vapor deposition, atomic layer deposition, and/or the like) may be used to deposit the layers 28, 30, 32 adjacent the support structure 14 sidewalls 22, 24 and the exposed area(s) 18, 20. FIG. 5 also illustrates an embodiment of the thin-film transistors 10 formed without the stopper layer 36, and having some of the fill layer 42 as part of the final structure.

Referring now to FIG. 6, two thin-film transistors 10 are formed on still another alternate embodiment of the support structure 14. In this embodiment, the sidewalls 22, 24 and the top 34 have an arcuate shape (e.g. semi-circular). The sidewalls 22, 24 are defined by a number of angles, including, for example, β₁, β₂ . . . βₙ.

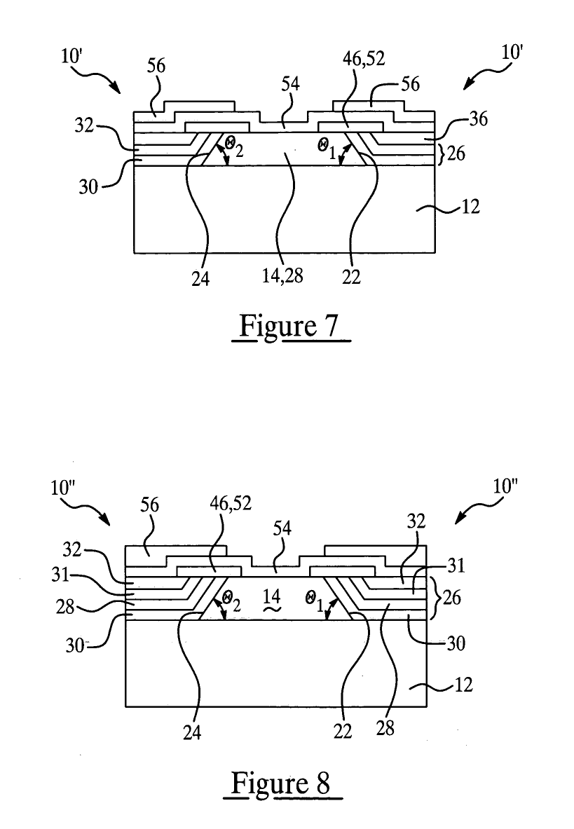

FIG. 7 depicts an alternate embodiment of the thin-film transistors 10′. In this embodiment, the support structure 14 is formed of a metal material and functions as the source or drain electrode 28. The insulating layer 30 is established adjacent the sidewalls 22, 24 of the support structure 14, and the other of the drain or source electrode 32 is established on the insulating layer. As such, this embodiment of the stack 26 includes the insulating layer 30 and the other of the drain or source electrode 32.

Referring now to FIG. 8, still another alternate embodiment of the thin-film transistors 10″ is depicted. In this embodiment, the insulating layer 30 is established adjacent the sidewalls 22, 24 and on the exposed portions 18, 20 adjacent to the support structure 14. The source/drain electrode 28, a second insulating layer 31, and the other of the drain/source 32 are then established on the insulating layer 30. In this embodiment, the stack 26 has two insulating layers 30, 31, a source/drain electrode 28, and a drain/source electrode 32.

It is to be understood that any suitable deposition and patterning techniques described herein may be used to form any of the embodiments of the thin-film transistors 10, 10′, 10″ disclosed herein.

Embodiments of the thin-film transistors 10, 10′, 10″ and methods of forming the same according to embodiments disclosed herein include, but are not limited to the following advantages. The thin-film transistors 10, 10′, 10″ advantageously have a substantially planar channel 52 geometry with respect to a substrate 12. The methods disclosed herein advantageously allow for controlling the channel length L to the sub-micron scale, generally without the direct patterning of films on this dimensional scale.

While embodiments have been described in detail, it will be apparent to those skilled in the art that the disclosed embodiments may be modified. Therefore, the foregoing description is to be considered exemplary rather than limiting.

What is claimed is:

1. A thin-film transistor, comprising:
a substrate having a substantially outwardly protruding support structure formed on a portion of a surface thereof such that at least a portion adjacent to the structure is exposed, the outwardly protruding support structure having opposed sidewalls sloped at an angle relative to the substrate surface;
a film stack established over the exposed portion and over at least a portion of an adjacent opposed sidewall, the film stack including an insulating layer; and
a channel material established on at least a portion of the film stack such that a channel is formed having a length substantially determined by a thickness of the insulating layer in relation to the angle of the adjacent opposed sidewall.

2. The thin-film transistor as defined in claim 1 wherein the support structure is one of a source electrode and a drain electrode, and wherein the film stack further comprises an other of a drain electrode and a source electrode established on the insulating layer.

3. The thin-film transistor as defined in claim 1 wherein the film stack further comprises a drain electrode and a source electrode, and wherein the insulating layer is established therebetween.

4. The thin-film transistor as defined in claim 3 wherein at least one of the source electrode or the drain electrode is adapted to be anodized.

5. The thin-film transistor as defined in claim 4 wherein the at least one of the source electrode or the drain electrode is formed from a material selected from aluminum, tantalum, tungsten, niobium, titanium, alloys thereof, and mixtures thereof.

6. The thin-film transistor as defined in claim 1, further comprising a stopper layer established on the film stack so that a top surface region of the film stack, a top of the support structure, and the stopper layer are substantially planar.

7. The thin-film transistor as defined in claim 6 wherein the channel material is established on the top surface region of the film stack and on at least a portion of the top of the support structure, wherein a gate dielectric is established on the stopper layer and on the channel material, and wherein a gate electrode is established on at least two portions of the gate dielectric such that a space is defined therebetween.

8. The thin-film transistor as defined in claim 6 wherein the stopper layer is an insulating layer.

9. The thin-film transistor as defined in claim 6 wherein the stopper layer has a thickness ranging from about 100 nm to about 1 μm.

10. The thin-film transistor as defined in claim 1 wherein the insulating layer is a dielectric layer.

11. The thin-film transistor as defined in claim 1 wherein the substantially outwardly protruding support structure has one of a substantially trapezoidal shape, a substantially arcuate shape, or a substantially bell-curve shape.

12. The thin-film transistor as defined in claim 1 wherein the channel length is measurable on a sub-micron scale.

13. The thin-film transistor as defined in claim 1 wherein the substantially outwardly protruding support structure is formed from a material selected from an oxide, a nitride, and combinations thereof, and has a thickness ranging from about 200 nm to about 5000 nm.

14. The thin-film transistor as defined in claim 1, further comprising a second exposed portion adjacent to the support structure and opposed to the exposed portion, wherein the film stack is established over each of the exposed portion and the second exposed portion, and over at least a portion of each of the adjacent opposed sidewalls.

15. The thin-film transistor as defined in claim 1 wherein the film stack further comprises:
one of a drain electrode and a source electrode established on the insulating layer;
a second insulating layer established on the one of the drain electrode and the source electrode; and
an other of a source electrode and a drain electrode established on the second insulating layer.

16. The thin-film transistor as defined in claim 1 wherein the angle relative to the substrate surface is an angle other than about 90°.

17. The thin-film transistor as defined in claim 1, further comprising:
a gate dielectric established on at least a portion of the channel material; and
a gate electrode established on at least a portion of the gate dielectric.

18. A thin-film transistor, comprising:
a substrate having a substantially outwardly protruding support structure formed on a portion of a surface thereof such that at least two opposed portions adjacent to the structure are exposed, the outwardly protruding support structure having opposed sidewalls sloped at an angle relative to the substrate surface;
a film stack established over each of the two portions and over at least a portion of an adjacent opposed sidewall, each film stack including:
one of a source electrode and a drain electrode;
an other of a drain electrode and a source electrode; and
an insulating layer established between the source and drain electrodes;
a stopper layer established adjacent each of the film stacks so that a top surface of each film stack, a top of the support structure, and the stopper layers are substantially planar;
a channel material established on two opposed ends of the top of the support structure and on at least a portion of the top surface of each film stack such that a channel is formed having a length substantially determined by a thickness of the insulating layer in relation to the angle of the adjacent opposed sidewall;
a gate dielectric established on each of the stop layers, on at least a portion of each of the channel materials, and on an exposed area of the top of the support structure; and
a gate electrode established on at least two opposed portions of the gate dielectric.

19. The thin-film transistor as defined in claim 18 wherein the substantially outwardly protruding support structure has one of a substantially trapezoidal shape, a substantially arcuate shape, or a substantially bell-curved shape.

20. The thin-film transistor as defined in claim 18 wherein at least one of the source electrode or the drain electrode is adapted to be anodized to form the insulating layer.

21. The thin-film transistor as defined in claim 20 wherein the at least one of the source electrode or the drain electrode is formed from a material selected from aluminum, tantalum, tungsten, niobium, titanium, alloys thereof, and mixtures thereof.

22. The thin-film transistor as defined in claim 18 wherein the insulating layer is a dielectric layer.

23. The thin-film transistor as defined in claim 18 wherein the stopper layer is an insulating layer.

24. The thin-film transistor as defined in claim 23 wherein the stopper layer has a thickness ranging from about 100 nm to about 1 μm.

25. The thin-film transistor as defined in claim 18 wherein the channel length is measurable on a sub-micron scale.

26. The thin-film transistor as defined in claim 18 wherein the substantially outwardly protruding support structure is formed from a material selected from an oxide, a nitride, and combinations thereof, and has a thickness ranging from about 200 nm to about 5000 nm.

27. The thin-film transistor as defined in claim 18 wherein the angle relative to the substrate surface is an angle other than about 90°.

28. A method of making a thin-film transistor, the method comprising:
forming a substantially outwardly protruding support structure on a portion of a substrate such that at least two opposed portions adjacent to the structure are exposed, and the outwardly protruding support structure has opposed sidewalls sloped at an angle relative to a substrate surface;
establishing a film stack over the outwardly protruding support structure and over the exposed portions, the stack including an insulating layer;
forming a substantially planar structure having at least two top surface regions of the film stack exposed;
establishing a channel material on the at least two top surface regions of the stack such that a channel is formed having a length substantially determined by a thickness of the insulating layer in relation to the angle of an adjacent opposed sidewall.

29. The method as defined in claim 28 wherein forming the substantially planar structure is accomplished by:
establishing a fill layer on the stack; and
removing at least a portion of the fill layer, a portion of the stack, and a portion of the support structure via planarization, whereby the substantially planar structure is formed and the at least two top surface regions of the stack are exposed.

30. The method as defined in claim 29 wherein prior to establishing the fill layer, the method further comprises establishing a stopper layer on the stack, wherein the fill layer is established on the stopper layer, and wherein removing at least a portion of the fill layer exposes the at least two top surface regions of the stack and a portion of the support structure, whereby the stopper layer acts as a partial planarization stop such that the substantially planar structure is formed.

31. The method as defined in claim 30, further comprising removing the stopper layer.

32. The method as defined in claim 29 wherein planarization is accomplished via chemical mechanical planarization.

33. The method as defined in claim 29 wherein establishing the fill layer is accomplished via a deposition process.

34. The method as defined in claim 28, further comprising:
establishing a gate dielectric on at least a portion of the channel materials and on the substantially planar structure; and
establishing a gate electrode on at least two opposed portions of the gate dielectric.

35. The method as defined in claim 28 wherein the support structure is one of a source electrode and a drain electrode, and wherein establishing the film stack further comprises establishing an other of a drain electrode and a source electrode on the insulating layer.

36. The method as defined in claim 28 wherein establishing the film stack further comprises:
establishing one of a drain electrode and a source electrode on the insulating layer;
establishing a second insulating layer on the one of the drain electrode and the source electrode; and
establishing an other of a source electrode and a drain electrode on the second insulating layer.

37. The method as defined in claim 28 wherein establishing the film stack further comprises:
establishing one of a drain electrode and a source electrode over the support structure and over the exposed portions;
forming the insulating layer on the one of the drain electrode and the source electrode; and
establishing an other of a source electrode and a drain electrode on the insulating layer.

38. The method as defined in claim 37 wherein the insulating layer is formed by electrochemical oxidation of a portion of one of the source electrode or the drain electrode.

39. The method as defined in claim 37 wherein establishing the source electrode and the drain electrode is accomplished by a deposition process and a patterning process.

40. The method as defined in claim 28 wherein the insulating layer is established by a deposition process in combination with at least one of photolithography or imprint lithography.

41. The method as defined in claim 40 wherein the deposition process is selected from physical vapor deposition, chemical vapor deposition, atomic layer deposition, and combinations thereof.

42. The method as defined in claim 28 wherein the substantially outwardly protruding support structure is formed by:
establishing a support material layer on the substrate surface;
establishing a photoresist layer on the support material layer;
patterning the photoresist layer;
heating the patterned photoresist layer; and
removing at least a portion of the patterned photoresist material and a portion of the support material layer, thereby forming the substantially outwardly protruding support structure.

43. The method as defined in claim 28 wherein the substrate surface has a layer established thereon, and wherein the support structure is established on the layer.

44. The method as defined in claim 28 wherein establishing the channel material is accomplished by deposition processes and patterning processes.

45. The method as defined in claim 28 wherein the angle relative to the substrate surface is an angle other than about 90°.

46. A thin-film transistor formed by the method of claim 28.

47. A method of making a thin-film transistor, the method comprising:
forming a substantially outwardly protruding support structure on a portion of a substrate such that at least a portion adjacent the structure is exposed, and the outwardly protruding support structure has opposed sidewalls sloped at an angle relative to a substrate surface;
establishing a stack over at least a portion of the outwardly protruding support structure and over the exposed portion, the stack including an insulating layer;
establishing a fill layer on the stack;
removing at least a portion of the fill layer, at least a portion of the stack, and at least a portion of the support structure via planarization, whereby a substantially planar structure is formed, and at least a top surface region of the stack is exposed;
establishing a channel material on the top surface region of the stack such that a channel is formed having a length substantially determined by a thickness of the insulating layer in relation to the angle of an adjacent opposed sidewall;
establishing a gate dielectric on at least a portion of the channel material and on the substantially planar structure; and
establishing a gate electrode on the gate dielectric.

48. The method as defined in claim 47 wherein the support structure is one of a source electrode and a drain electrode, and wherein establishing the stack further comprises establishing an other of a drain electrode and a source electrode on the insulating layer.

49. The method as defined in claim 47 wherein establishing the stack further comprises:
establishing one of a drain electrode and a source electrode over the support structure and over the exposed portion;
forming the insulating layer on the one of the drain electrode and the source electrode; and
establishing an other of a source electrode and a drain electrode on the insulating layer.

50. The method as defined in claim 47 wherein establishing the stack further comprises:
establishing one of a drain electrode and a source electrode on the insulating layer;
establishing a second insulating layer on the one of the drain electrode and the source electrode; and
establishing an other of a source electrode and a drain electrode on the second insulating layer.

51. A thin-film transistor, comprising:
a substrate having a surface;
a thin-film stack established over at least a portion of the surface, the thin-film stack including:
a source electrode;
a drain electrode; and
means for insulating the source and drain electrodes;
means for supporting the thin-film stack, the supporting means substantially outwardly protruding from the surface and having at least two opposed sidewalls at an angle relative to the surface; and
means for generating a channel having a length substantially determined by a thickness of the means for insulating in relation to the angle of the at least two opposed sidewalls.

52. A display device, comprising:
a thin-film transistor operatively disposed in the display device, the thin-film transistor comprising:
a substrate having a substantially outwardly protruding support structure formed on a portion of a surface thereof such that at least a portion adjacent to the structure is exposed, the outwardly protruding support structure having opposed sidewalls sloped at an angle relative to the substrate surface;
a film stack established over the exposed portion and over at least a portion of an adjacent opposed sidewall, the film stack comprising an insulating layer;
a channel material established on at least a portion of the film stack such that a channel is formed having a length substantially determined by a thickness of the insulating layer in relation to the angle of the adjacent opposed sidewall;
a gate dielectric established on at least a portion of the channel material; and
a gate electrode established on at least a portion of the gate dielectric.
